(19) United States
(12) Patent Application Publication
(10) Pub. No.: US 2002/0164424 A1
(43) Pub. Date: Nov. 7, 2002

(54) Method for fabricating N-type doped polycrystalline silicon

(76) Inventors: Chih Yuan Huang, Taipei (TW); Chin Hsiang Lin, Hsin-Yi St. Nantou (TW)

Correspondence Address: J.C. Patents, Inc., Suite 114, 1340 Reynolds Ave., Irvine, CA, 92614, US

(21) Appl. No.: 09/922,253

(22) Filed: Aug. 3, 2001

(30) Foreign Application Priority Data
May 4, 2001 (TW) 90110700

(51) Int. Cl. C23C 16/00

(52) U.S. Cl. 427/255.393; 427/255.28

(57) ABSTRACT

A method for fabricating N-type doped polycrystalline silicon. A reactive gas source is introduced into a gas deposition reaction chamber and a chemical vapor deposition process is performed to form an N-type doped polycrystalline film.

### CROSS-REFERENCE TO RELATED APPLICATION

This application claims the priority benefit of Taiwan application serial No. 90110700, filed May 4, 2001.

### BACKGROUND OF THE INVENTION

1. Field of the Invention

The present invention relates to a method for fabricating doped polycrystalline silicon, and in particular, a method for fabricating N-type doped polycrystalline silicon.

2. Description of the Related Art

The formation of polycrystalline silicon plays an important role in the IC fabrication process, and particularly, in the course of MOS gate formation or as polysilicon interconnect structure. Generally, Low Pressure Chemical Vapor Deposition (LPCVD) is employed in deposition of polycrystalline silicon. In order to reduce the rate of resistance of the polycrystalline silicon, a dopant is implanted into the polycrystalline silicon layer so as to enhance the conductivity of the polycrystalline silicon layer. The method of doping polycrystalline silicon includes ion implantation following deposition reaction to implant a dopant, or by high temperature diffusion method to drive in a dopant.

When using the above dopant implantation subsequent to the low pressure chemical vapor phase deposition reaction to proceed with doping of polycrystalline silicon, the reaction mechanism is different with respect to different dopants in the course of deposition and this has great impact on the deposition rate of the polycrystalline silicon film. For example, when depositing p-type doped polycrystalline silicon, Phosphine (B₂H₆) is used as a dopant gas source and by a slight increase of the concentration thereof, the reaction rate is greatly increased, and B₂H₆ possesses the effect of a catalyst. In the process of deposition of N-type doped polycrystalline silicon, PH₃ is used as a dopant gas source. Due to the fact that PH₃ has a chemically stereo structure effect, increasing of the concentration of PH3 decreases the reaction rate.

In addition, suicides or silane containing chlorine are used as a reaction gas source in deposition of polycrystalline silicon, and the growth rate of polycrystalline silicon film decreases as the chlorine content of the reaction gas source increases. Thus, silane is frequently used as a reaction gas source in the common polycrystalline silicon deposition process; as a result, the selectivity of reaction gas source in the fabrication process is restricted.

Besides, in the common polycrystalline deposition process, the deposition rate is controlled by changes in temperature. Elevating the temperature so as to increase the deposition rate simultaneously leads to a change in the polycrystalline silicon structure.

### SUMMARY OF THE INVENTION

Accordingly, it is an object of the present invention to provide a method for fabricating N-type doped polycrystalline silicon, wherein silane containing chlorine is used as a reaction gas source to improve the deposition rate of polycrystalline silicon in chemical deposition process.

Yet another object of the present invention is to provide a method for fabricating N-type doped polycrystalline silicon, wherein a catalyst is used in improving the deposition rate of polycrystalline silicon in a chemical deposition process using suicides or silane containing chlorine as a reaction gas.

A further object of the present invention is to provide a method for fabricating N-type doped polycrystalline silicon that avoids a temperature change in the fabrication process with respect to polycrystalline silicon structure via a chemical method, by employing a catalyst to improve deposition rate so as to reduce the thermal budget.

In order to achieve the above objectives, the present invention provides a method for fabricating N-type doped polycrystalline silicon. In this method, a wafer is provided. The wafer is placed in a reaction chamber. A reaction gas source, an N-type doped gas source and a catalyst are introduced into the reaction chamber. Chemical vapor phase deposition is then performed to form an N-type doped polycrystalline silicon film.

The present invention is characterized by the use of B₂H₆ as a catalyst to improve the deposition rate of polycrystalline silicon in a chemical deposition process employing silicides or silane containing chlorine as reaction gas source. In the inventive process, a temperature change with respect to polycrystalline silicon structure is avoided so as to reduce the thermal budget.

### BRIEF DESCRIPTION OF THE DRAWINGS

FIG. 1 is a schematic diagram illustrating the fabrication of N-type doped polycrystalline silicon according to a first preferred embodiment of the present invention.

FIG. 2 is aschematic diagram illustrating the fabrication of N-type doped polycrystalline silicon according to a second preferred embodiment of the present invention.

### DESCRIPTION OF THE PREFERRED EMBODIMENTS

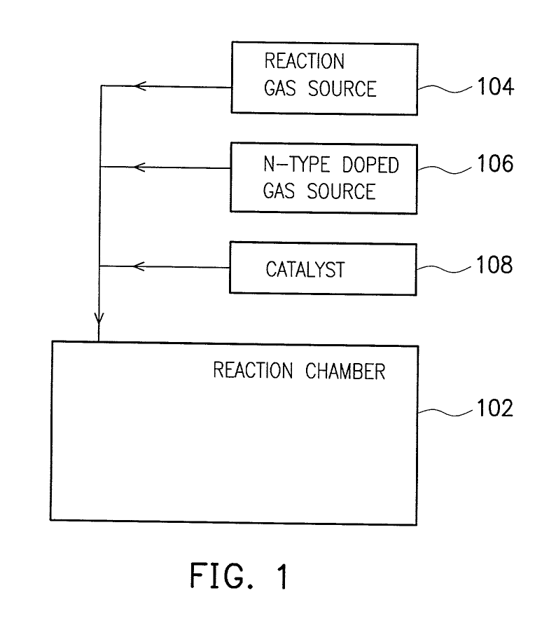

FIG. 1 is aschematic diagram illustrating the fabrication of N-type doped polycrystalline silicon of a first preferred embodiment in accordance with the present invention.

As shown in FIG. 1, a semiconductor wafer 100 is provided and the semiconductor wafer 100 is placed in a reaction chamber 102.

Next, a reaction gas source 104, N-type doped gas source 106 and a catalyst 108 are introduced into the reaction chamber. Examples of the reaction gas source 104 are silicides or silane containing chlorine, including silane (SiH₄), dichlorosilane (SiH₂Cl₂), trichlorosilane (SiHCl₃) and tetrachlorosilane (SiCl₄). An example of the N-type doped gas source 106 is PH₃. An example of the catalyst 108 is an agent that increases polycrystalline silicon deposition rate, including B₂H₆. Next, a chemical vapor phase deposition process is carried out to form N-type doped polycrystalline silicon.

In the above fabrication process, the addition of a catalyst 108 into the reaction chamber 102 increases the deposition rate of polycrystalline silicon, and therefore, silane-containing chlorine can be used as the reaction gas source in polycrystalline silicon chemical vapor phase deposition so as to increase the selectivity of gas in the fabrication process.

In fabricating N-type doped polycrystalline silicon, PH₃ is used as N-type doped gas source 106. Due to the fact that PH₃ has a chemically stereo structure, the increase in concentration of PH3 decreases the deposition rate of polycrystalline silicon deposition. Therefore, in the above fabrication process, a catalyst 108, for example, B₂H₆, which can increase the deposition rate of polycrystalline silicon, is added. A slight increase in the concentration of the catalyst 108 will greatly increase the deposition rate of polycrystalline silicon. Although the use B₂H₆ as catalyst will cause p-type dopant implantation into the polycrystalline silicon, less catalyst 108 than the N-type doped gas source 106 is used, and the deposited doped polycrystalline silicon is still N-type doped polycrystalline silicon.

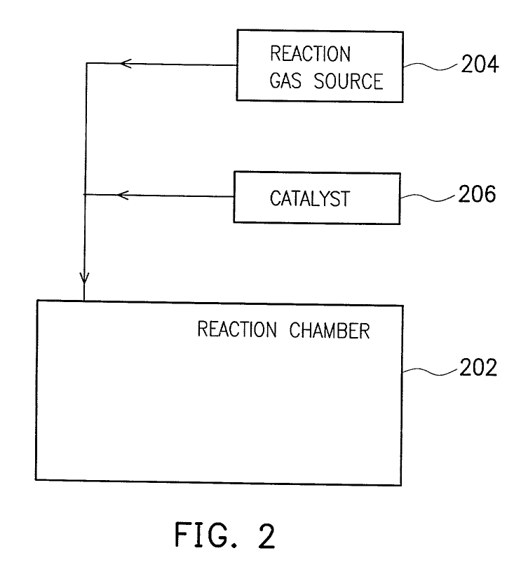

FIG. 2 is aschematic diagram illustrating the fabrication of N-type doped polycrystalline silicon according to a second preferred embodiment of the present invention.

As shown in FIG. 2, a semiconductor wafer 200 is provided and the semiconductor wafer 200 is placed in a reaction chamber 202.

Next, a reaction gas source 204 and a catalyst 206 are introduced into the reaction chamber 204, and the reaction gas source 204 is, for example, silane containing chlorine, SiH₂Cl₂, SiHCl₂ or SiCl₄. The catalyst 206, for example, is an agent that can increase the deposition rate of polycrystalline silicon, including B₂H₆. Next, a chemical vapor phase deposition process is carried out so that the polycrystalline silicone layer is formed on the wafer.

Next, an N-type dopant implantation step is carried out so as to form an N-type doped polycrystalline silicon layer. In the process of N-type dopant implantation step, for instance, the ion implantation step, phosphorous ions are implanted.

In the above fabrication process, due to the fact that the addition of a catalyst 206 to the reaction chamber 202 increases the deposition rate of polycrystalline silicon, silane-containing chlorine is used as the reaction gas source of polycrystalline chemical vapor phase deposition so as to increase the selectivity of gas in the fabrication process.

Additionally, although B₂H₆ is used as catalyst to implant a p-type dopant into the polycrystalline silicon, the amount of catalyst 206 used is small. Thus, merely by adding a dopant implantation step, the deposited doped polycrystalline silicon is N-type doped polycrystalline silicon.

In accordance with the preferred embodiments of the present invention, the present invention has advantages as follows (1) SiH₂Cl₂, SiHCl₃ and SiCl₄ are used as reaction gas source in the chemical deposition fabrication process of polycrystalline silicon so that the selectivity of gas is increased. (2) By means of a catalyst in the polycrystalline chemical deposition fabrication process, the polycrystalline silicon deposition rate is increased by use of silicides or silane containing chlorine as the reaction gas source. (3) A temperature change with respect to polycrystalline silicon structure in the fabrication process is avoided, while a chemical method, utilizing a catalyst is employed, to improve deposition rate so as to reduce the thermal budget.

While the invention has been described with respect to preferred embodiment, it will be clear to those skilled in the art that modifications and improvements may be made to the invention without departing from the spirit and scope of the invention. Therefore, the invention is not to be limited by the specific illustrative embodiment, but only by the scope of the appended claims.

What is claimed is:

1. A method for fabricating N-type doped polycrystalline silicon, comprising:
providing a wafer;
placing the wafer in a reaction chamber;
introducing a reaction gas source, an N-type doped gas source and a gas source of a catalyst into the reaction chamber; and
performing a chemical vapor deposition process to form an N-type doped polycrystalline silicon film.

2. The method of claim 1, wherein the reaction gas source is selected from a group consisting of SiH₂Cl₂, SiHCl₃ and SiCl₄.

3. The method of claim 2, wherein the catalyst includes B₂H₆.

4. The method of claim 1, wherein the reaction gas includes SiCl₄.

5. The method of claim 2, wherein the catalyst includes B₂H₆.

6. The method of claim 1, wherein the catalyst includes B₂H₆.

7. The method of claim 1, wherein the doped gas source includes PH₃.

8. A method for fabricating N-type doped polycrystalline silicon, comprising:
providing a wafer;
placing the wafer in a reaction chamber;
introducing silane containing chlorine, PH₃ and B₂H₆ as gas source into the reaction chamber for increasing deposition rate, wherein an amount of B₂H₆ is lower than that of the PH₃; and
performing a chemical vapor deposition process to form a N-type doped polycrystalline silicon film.

9. The method of claim 8, wherein the silane containing chlorine is selected from a group consisting of SiH₂Cl₂, SiHCl₃ and SiCl₄.

10. A method for fabricating N-type doped polycrystalline silicon, comprising:
providing a wafer,
placing the wafer in a reaction chamber,
introducing silane containing chlorine and a catalyst as a gas source into the reaction chamber to increase rate of deposition;
performing a chemical vapor deposition process to form a polycrystalline film; and
performing an N-type dopant implantation process to form an N-type doped polycrystalline silicon film.

11. The method of claim 10, wherein the silane containing chlorine is selected from a group consisting of SiH₂Cl₂, SiHCl₃ and SiCl₄.

12. The method of claim 10, wherein the catalyst includes B₂H₆.

13. The method of claim 10, wherein the N-type dopant implantation process includes ion implantation.

14. The method of claim 10, wherein the dopant of the N-type dopant implantation process includes phosphorous ions.
